(19) United States
(12) Patent Application Publication
(10) Pub. No.: US 2014/0028353 A1
(43) Pub. Date: Jan. 30, 2014

(54) High speed signal detecting circuit and system

(71) Applicant: IPGoal Microelectronics (Sichuan) Co., Ltd., Chengdu (CN)

(72) Inventor: Fangping Fan, Chengdu (CN)

(73) Assignee: IPGoal Microelectronics (Sichuan) Co., Ltd., Chengdu (CN)

(21) Appl. No.: 13/948,701

(22) Filed: Jul. 23, 2013

(30) Foreign Application Priority Data
Jul. 24, 2012 (CN) 201210256790.0

(51) Int. Cl. H03K 5/153

(52) U.S. Cl. CPC H03K 5/153
USPC 327/77

(57) ABSTRACT

A high speed signal detecting circuit includes an input terminal, a reference terminal, an output terminal, a power source terminal, a ground terminal, a front-end receiver which is connected to the input terminal, the reference terminal and the ground terminal, a secondary amplifier which is connected to the front-end receiver and the ground terminal, a final amplifier which is connected to the secondary receiver, the output terminal, the power source terminal and the ground terminal, and a biasing circuit which is connected to the front-end receiver, the secondary amplifier, the final amplifier, the power source terminal and the ground terminal. A high speed signal detecting method is also provided to precisely detect high speed signal and change a detection threshold value of the high speed signals by changing a voltage value of the reference terminal and thus has a great flexibility.

### BACKGROUND OF THE PRESENT INVENTION

1. Field of Invention

The present invention relates to a signal detecting circuit, and more particularly to a high speed signal detecting circuit having a high bandwidth and a high gain.

2. Description of Related Arts

The high speed signal detecting circuit is for detecting signals which have very high frequencies and thus is generally required to have a very high bandwidth; besides, when the detection threshold value of the signals are set, in order to reduce the detection error, the high speed signal detecting circuit is further required to have a high gain.

According to prior arts, in order to simultaneously accomplish the high bandwidth and the high gain, a compromise between the high bandwidth and the high gain is usually adopted, which limits a simultaneous increase in the bandwidth and the gain of the detecting circuit and accordingly affects the design of the detecting circuits. Thus, it is necessary to provide a signal detecting circuit which is capable of raising a gain and a bandwidth thereof simultaneously.

### SUMMARY OF THE PRESENT INVENTION

An object of the present invention is to provide a high speed signal detecting circuit which simultaneously has a high gain and a high bandwidth, and a system thereof

A high speed signal detecting circuit comprises an input terminal, a reference terminal, an output terminal, a power source terminal, a ground terminal, a front-end receiver which is connected to the input terminal, the reference terminal and the ground terminal, a secondary amplifier which is connected to the front-end receiver and the ground terminal, a final amplifier which is connected to the secondary amplifier, the output terminal, the power source terminal and the ground terminal, and a biasing circuit which is connected to the front-end receiver, the secondary amplifier, the final amplifier, the power source terminal and the ground terminal. The front-end receiver comprises a first field effect transistor (FET) which is connected to the input terminal and the ground terminal, and a second FET which is connected to the reference terminal and the ground terminal. The secondary amplifier comprises a third FET connected to the first FET, a fourth FET connected to the second FET, a fifth FET connected to the third FET, a sixth FET connected to the fourth FET, a first resistor connected to the third FET, a second resistor connected to the fourth FET, a third resistor which is connected to the first resistor, the second resistor and the power source terminal, a fourth resistor connected to the fifth FET, a fifth resistor connected to the sixth FET, and a sixth resistor which is connected to the fourth resistor, the fifth resistor and the power source terminal. The final amplifier comprises a seventh FET connected to the fifth FET, an eighth FET which is connected to the sixth FET and the output terminal, a ninth FET which is connected to the seventh FET and the power source terminal, a tenth FET which is connected to the seventh FET, the eighth FET, the ninth FET, the output terminal and the power source terminal. The biasing circuit comprises a first current source which is connected to the first FET, the third FET and the power source terminal, a second current source which is connected to the second FET, the fourth FET and the power source terminal, a third current source which is connected to the third FET, the fourth FET and the power source terminal, a fourth current source which is connected to the fifth FET, the sixth FET and the power source terminal, and a fifth current source which is connected to the seventh FET, the eighth FET and the power source terminal.

A high speed signal detecting method comprises a step of providing a device comprising an input terminal, a reference terminal, an output terminal, a power source terminal, a ground terminal, a front-end receiver for comparing a signal of the input terminal with a signal of the reference terminal, a secondary amplifier for amplifying output signals VO1 and VO2 which are outputted by the front-end receiver, a final amplifier for amplifying output signals V2A and V2B which are outputted by the secondary amplifier and transforming the output signal V2A and the output signal V2B into a single terminal output signal, and a biasing circuit for supplying the front-end receiver, the secondary amplifier and the final amplifier with bias current sources. The high speed signal detecting method further comprises steps of: inputting a detection threshold value of high speed signals by the reference terminal, inputting a high speed signal via the input terminal, comparing the high speed signal inputted by the input terminal with the detection threshold value inputted by the reference terminal, then amplifying to obtain the output signals VO1 and VO2 which enter the secondary amplifier; comparing the output signal VO1 with the output signal VO2 to form a comparison result, amplifying the comparison result to obtain the output signals V2A and V2B and outputting the output signal V2A and the output signal V2B into the final amplifier by the secondary amplifier; and comparing the output signal V2A with the output signal V2B to obtain a comparison result, transforming the comparison result into a single-terminal output signal and outputting the single-terminal output signal into the output terminal by the final amplifier.

Compared with prior arts, the high speed signal detecting circuit provided by the present invention is able to precisely detect the high speed signals; the high speed signal detecting circuit is also able to change the detection threshold value of the high speed signals by changing a voltage value of the reference terminal and thus has a great flexibility.

These and other objectives, features, and advantages of the present invention will become apparent from the following detailed description, the accompanying drawings, and the appended claims.

### BRIEF DESCRIPTION OF THE DRAWINGS

FIG. 1 is a system block diagram of a high speed signal detecting circuit according to a preferred embodiment of the present invention.

FIG. 2 is a sketch view of the high speed signal detecting circuit according to the preferred embodiment of the present invention.

### DETAILED DESCRIPTION OF THE PREFERRED EMBODIMENT

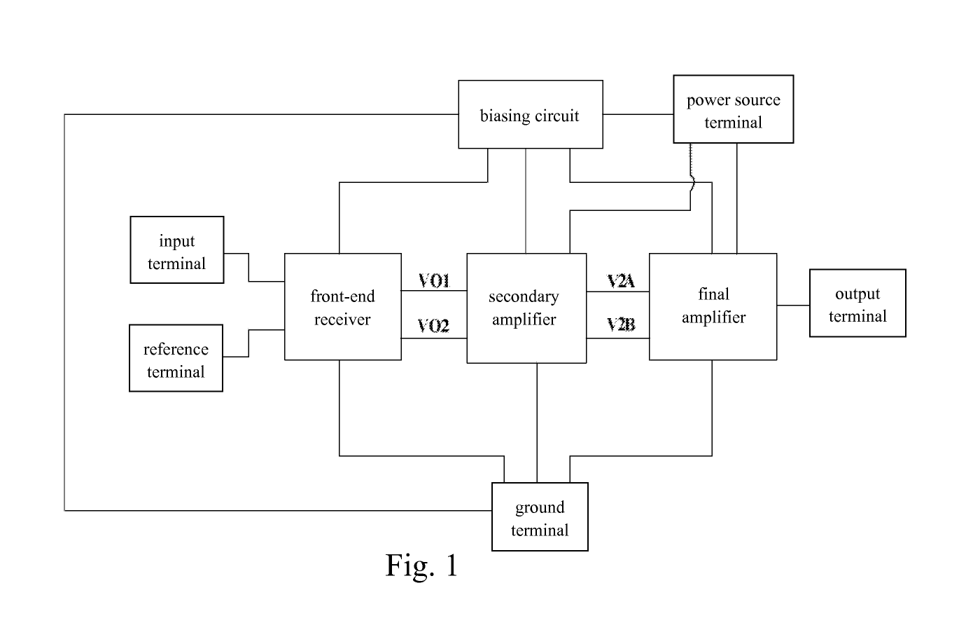

Referring to FIG. 1 of the drawings, according to a preferred embodiment of the present invention, a high speed signal detecting method comprise a step of: providing a device comprising an input terminal VIN, a reference terminal VREF, an output terminal VOUT, a power source terminal VCC, a ground terminal GND, a front-end receiver for comparing a signal of the input terminal VIN with a signal of the reference terminal VREF, a secondary amplifier for amplifying output signals VO1 and VO2 which are outputted by the front-end receiver, a final amplifier for amplifying output signals V2A and V2B which are outputted by the secondary amplifier and changing the output signal V2A and the output signal V2B into a single-terminal output signal, and a biasing circuit for supplying the front-end receiver, the secondary amplifier and the final amplifier with bias current sources.

According to the preferred embodiment of the present invention, the high speed signal detecting method further comprises steps of: inputting a detection threshold value of high speed signals by the reference terminal, inputting a high speed signal via the input terminal, and amplifying the high speed signal by the front-end receiver to obtain the output signals VO1 and VO2 which enter the secondary amplifier; secondarily amplifying the output signal VO1 and the output signal VO2 to obtain the output signals V2A and V2B which enter the final amplifier by the secondary amplifier; and amplifying the output signals V2A and V2B, transforming the output signals V2A and V2B into a single-terminal output signal and outputting the single-terminal output signal into the output terminal by the final amplifier.

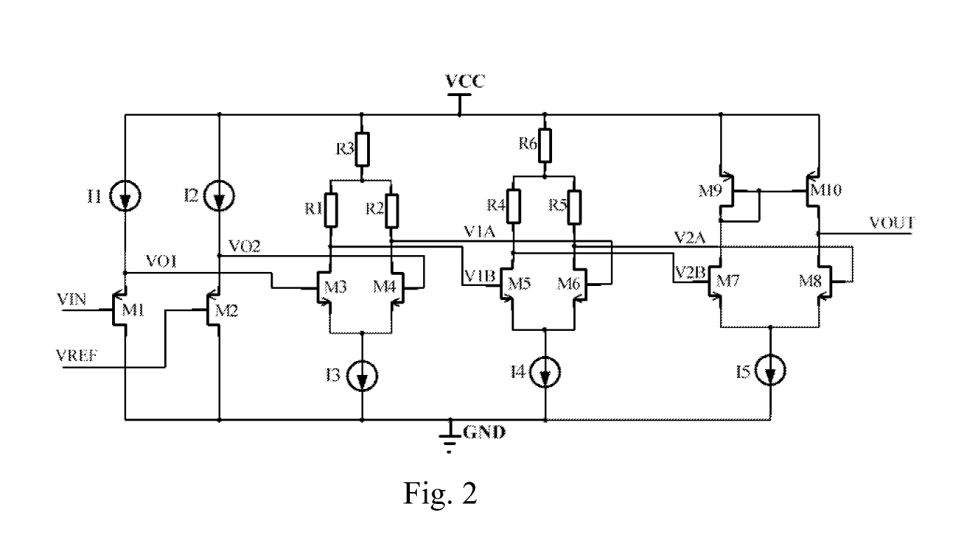

Further, referring to FIG. 2, a high speed signal detecting circuit comprises an input terminal VIN, a reference terminal VREF, an output terminal VOUT, a power source terminal VCC, a ground terminal GND, a front-end receiver which is connected to the input terminal VIN, the reference terminal VREF and the ground terminal GND, a secondary amplifier which is connected to the front-end receiver and the ground terminal GND, a final amplifier which is connected to the secondary amplifier, the output terminal VOUT, the power source terminal VCC and the ground terminal GND, and a biasing circuit which is connected to the front-end receiver, the secondary amplifier, the final amplifier, the power source terminal VCC and the ground terminal GND. The front-end receiver comprises a first FET M1 which is connected to the input terminal VIN and the ground terminal GND, and a second FET M2 which is connected to reference terminal VREF and the ground terminal GND. The secondary amplifier comprises a third FET M3 connected to the first FET M1, a fourth FET M4 connected to the second FET M2, a fifth FET M5 connected to the third FET M3, a sixth FET M6 connected to the fourth FET M4, a first resistor R1 connected to the third FET M3, a second resistor R2 connected to the fourth FET M4, a third resistor R3 which is connected to the first resistor R1, the second resistor R2 and the ground terminal VCC, a fourth resistor R4 connected to the fifth FET M5, a fifth resistor R5 connected to the sixth FET M6, and a sixth resistor R6 which is connected to the fourth resistor R4, the fifth resistor R5 and the power source terminal VCC. The final amplifier comprises a seventh FET M7 connected to the fifth FET M5, an eighth FET M8 which is connected to the sixth FET M6 and the output terminal VOUT, a ninth FET M9 which is connected to the seventh FET M7 and the power source terminal VCC, and a tenth FET which is connected to the seventh FET M7, the eighth FET M8, the ninth FET M9, the output terminal VOUT and the power source terminal VCC. The biasing circuit comprises a first current source Il which is connected to the first FET M1, the third FET M3 and the power source terminal VCC, a second current source I2 which is connected to the second FET M2, the fourth FET M4 and the power source terminal VCC, a third current source I3 which is connected to the third FET M3, the fourth FET M4 and the power source terminal VCC, a fourth current source I4 which is connected to the fifth FET M5, the sixth FET M6 and the power source terminal VCC, and a fifth current source I5 which is connected to the seventh FET M7, the eighth FET M8 and the power source terminal VCC.

According to the preferred embodiment of the present invention, the high speed signal detecting circuit has following connections. A gate electrode of the first FET M1 is connected to the input terminal VIN; and a gate electrode of the second FET M2 is connected to the reference terminal VREF. A source electrode of the first FET M1, a gate electrode of the third FET M3 and a first terminal of the first current source I1 are connected; a source electrode of the second FET M2, a gate electrode of the fourth FET M4 and a first terminal of the second current source I2 are connected; a drain electrode of the third FET M3, a gate electrode of the fifth FET M5 and a first terminal of the first resistor R1 are connected; a drain electrode of the fourth FET M4, a gate electrode of the sixth FET M6 and a first terminal of the second resistor R2 are connected; and a second terminal of the first resistor R1, a second terminal of the second resistor R2 and a first terminal of the third resistor R3 are connected. A drain electrode of the fifth FET M5, a gate electrode of the seventh FET M7 and a first terminal of the fourth resistor R4 are connected; a drain electrode of the sixth FET M6, a gate electrode of the eighth FET M8 and a first terminal of the fifth resistor R5 are connected. A second terminal of the fourth resistor R4, a second terminal of the fifth resistor R5 and a first terminal of the sixth resistor R6 are connected. A drain electrode of the seventh FET M7, a gate electrode and a drain electrode of the ninth FET M9 and a gate electrode of the tenth FET M10 are connected. A drain electrode of the tenth FET M10, a drain electrode of the eighth FET M8 and the output terminal VOUT are connected. A source electrode of the seventh FET M7, a source electrode of the eighth FET M8 and a first terminal of the fifth current source I5 are connected. A source electrode of the fifth FET M5, a source electrode of the sixth FET M6 and a first terminal of the fourth current source I4 are connected. A source electrode of the third FET M3, a source electrode of the fourth FET M4 and a first terminal of the third current source I3 are connected. A second terminal of the first current source I1, a second terminal of the second current source I2, a second terminal of the third resistor R3, a second terminal of the sixth resistor R6, a source electrode of the ninth FET M9 and a source electrode of the tenth FET M10 are all connected to the power source terminal VCC. A drain electrode of the first FET M1, a drain electrode of the second FET M2, a second terminal of the third current source I3, a second terminal of the fourth current source I4 and a second terminal of the fifth current source IS are all connected to the ground terminal GND.

According to the preferred embodiment of the present invention, the high speed signal detecting circuit has following system working principles. Firstly, the reference terminal VREF is set to be at a fixed level, i.e., the detection threshold value of high speed signals, and then a high speed signal is inputted via the input terminal VIN, received by the front-end receiver and then outputted via the output signals VO1 and VO2; then the high speed signal enters the secondary amplifier and is amplified by the secondary amplifier to obtain the output signals V2A and V2B; the output signals V2A and V2B enter the final amplifier and are transformed into a single-terminal output signal by the final amplifier; and the single-terminal output signal is outputted via the output terminal.

Each amplifier is analyzed as follows.

The front-end receiver has a direct current gain A1=gma/(gma+gmb), wherein gma=gm1=gm2; gmb=gmb1=gmb2; gm1 and gm2 are respectively small signal transconductances of the first FET M1 and the second FET M2; gmb1 and gmb2 are respectively bulk-effect small signal transconductances of the first FET M1 and the second FET M2; gma is far bigger than gmb, so
A1=gma/(gma+gmb)≈1, i.e., the front-end receiver has a low gain.

The front-end receiver has an alternating current characteristic that p1=(gma+gmb)/C1, wherein C1 is an equivalent capacitance of an output terminal of the front-end receiver; gma+gmb is relatively big, so the pole p1 is also relatively big, i.e., the front-end receiver has a high bandwidth. In other words, the front-end receiver has the low gain and the high bandwidth and is able to receive the inputted signal without attenuation and output the signal into the secondary amplifier.

The secondary amplifier has a direct current gain A2=(gmc*R)/2, wherein gmc=gm3=gm4=gm5=gm6; R=R1=R2=R4=R5; gm3, gm4, gm5 and gm6 are respectively small signal transconductances of the third FET M3, the fourth FET M4, the fifth FET M5 and the sixth FET M6; a value of R is relatively small and usually no more than 5 KΩ so a value of A2 is unlikely too big, i.e., the secondary amplifier has a medium gain.

The secondary amplifier has an alternating current characteristic that p2=1/(R*C2) and p3=1/(R*C2), wherein C2 is an equivalent capacitance of an output terminal of the secondary amplifier; R is relatively small and thus the poles, p2 and p3, are both relatively big, i.e., the secondary amplifier has a high bandwidth; besides, p2 and p3 coincide with each other, i.e., the secondary amplifier has a function of filtering for rapidly attenuating noises which have higher frequencies than the signal. The secondary amplifier has the medium gain and the high bandwidth.

The final amplifier has a direct current gain A3=gmd*(ron H rop), wherein gmd=gm7=gm8; gm7 and gm8 are respectively small signal transconductances of the seventh FET M7 and the eight FET M8; rop is a small signal resistor of the seventh FET M7 and ron is a small signal resistor of the eighth FET M8; ron and rop are commonly relatively big and usually bigger than 100 KΩ so A3 is relatively big, i.e., the final amplifier has a high gain.

The final amplifier has an alternating current characteristic that p4=1/(C3*(ron≡rop)), wherein C3 is an equivalent capacitance of the output terminal VOUT; ron and rop are relatively big, so p4 is relatively small, i.e., the final amplifier has a low bandwidth. The final amplifier has the high gain and the low bandwidth and thus is able to amplify signal amplitude.

As a conclusion, the front-receiver and the secondary amplifier both have the high bandwidth, which ensures that the high speed signal passes without attenuation, and also have the medium gain, which ensures that a swing difference between the high speed signal and the reference terminal is amplified, in such a manner that the final amplifier is able to precisely receive, amplify and output the high speed signal into the output terminal VOUT, so as to accomplish a detection of the high speed signal.

An analysis of functions of the high speed signal detecting circuit is as follows.

If the signal swing of the input terminal VIN is always smaller than that of the reference terminal VREF, the swing of the output signal VO1 is also always smaller than the swing of the output signal VO2 after the signal passes through the front-end receiver; the swing of the output signal V2B is also always smaller than the swing of the output signal V2A after the signal is amplified by the secondary amplifier; further, after the signal is amplified by the final amplifier, the output terminal VOUT outputs a low level all the time. In other words, no high speed signal is detected by the high speed signal detecting circuit.

If the signal swing of the input terminal VIN is always larger than that of the reference terminal VREF, the swing of the output signal VO1 is also always larger than the swing of the output signal VO2 after the signal passes through the front-end receiver; the swing of the output signal V2B is also always larger than the swing of the output signal V2A after the signal is amplified by the secondary amplifier; further, after the signal is amplified by the final amplifier, the output terminal VOUT outputs an effective signal. In other words, the high speed signal is detected by the high speed signal detecting circuit detect.

According to the above analyses, the high speed signal detecting circuit provided by the present invention is able to detect the high speed signal precisely and to change the detection threshold value of the high speed signals by changing a voltage value of the reference terminal VREF and thus has a great flexibility.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A high speed signal detecting circuit, comprising an input terminal, a reference terminal, an output terminal, a power source terminal, a ground terminal, a front-end receiver which is connected to said input terminal, said reference terminal and said ground terminal, a secondary amplifier which is connected to said front-end receiver and said ground terminal, a final amplifier which is connected to said secondary amplifier, said output terminal, said power source terminal and said ground terminal, and a biasing circuit which is connected to said front-end receiver, said secondary amplifier, said final amplifier, said power source terminal and said ground terminal.

2. The high speed signal detecting circuit, as recited in claim 1, wherein said front-end receiver comprises a first FET which is connected to said input terminal and said ground terminal, and a second FET which is connected to said reference terminal and said ground terminal; said secondary amplifier comprises a third FET connected to said first FET, a fourth FET connected to said second FET, a fifth FET connected to said third FET, a sixth FET connected to said fourth FET, a first resistor connected to said third FET, a second resistor connected to said fourth FET, a third resistor which is connected to said first resistor, said second resistor and said power source terminal, a fourth resistor connected to said fifth FET, a fifth resistor connected to said sixth FET, and a sixth resistor which is connected to said fourth resistor, said fifth resistor and said power source terminal; said final amplifier comprises a seventh FET connected to said fifth FET, an eighth FET which is connected to said sixth FET and said output terminal, a ninth FET which is connected to said seventh FET and said power source terminal, and a tenth FET which is connected to said seventh FET, said eighth FET, said ninth FET, said output terminal and said power source terminal; and said biasing circuit comprises a first current source which is connected to said first FET, said third FET and said power source terminal, a second current source which is connected to said second FET, said fourth FET and said power source terminal, a third current source which is connected to said third FET, said fourth FET and said power source terminal, a fourth current source which is connected to said fifth FET, said sixth FET and said power source terminal, and a fifth current source which is connected to said seventh FET, said eighth FET and said power source terminal.

3. The high speed signal detecting circuit, as recited in claim 2, wherein a gate electrode of said first FET is connected to said input terminal; a gate electrode of said second FET is connected to said reference terminal; a source electrode of said first FET, a gate electrode of said third FET and a first terminal of said first current source are connected; and a source electrode of said second FET, a gate electrode of said fourth FET and a first terminal of said second current source are connected.

4. The high speed signal detecting circuit, as recited in claim 3, wherein a drain electrode of said third FET, a gate electrode of said fifth FET and a first terminal of said first resistor are connected; a drain electrode of said fourth FET, a gate electrode of said sixth FET and a first terminal of said second resistor are connected; a second terminal of said first resistor, a second terminal of said second resistor and a first terminal of said third resistor are connected; a drain electrode of said fifth FET, a gate electrode of said seventh FET and a first terminal of said fourth resistor are connected; a drain electrode of said sixth FET, a gate electrode of said eighth FET and a first terminal of said fifth resistor are connected; a second terminal of said fourth resistor, a second terminal of said fifth resistor and a first terminal of said sixth resistor are connected; a source electrode of said fifth FET, a source electrode of said sixth FET and a first terminal of said fourth current source are connected; and a source electrode of said third FET, a source electrode of said fourth FET and a first terminal of said third current source are connected.

5. The high speed signal detecting circuit, as recited in claim 4, wherein a drain electrode of said seventh FET, a gate electrode and a drain electrode of said ninth FET and a gate electrode of said tenth FET are connected; a drain electrode of said tenth FET, a drain electrode of said eighth FET and said output terminal are connected; and a source electrode of said seventh FET, a source electrode of said eighth FET and a first terminal of said fifth current source are connected.

6. The high speed signal detecting circuit, as recited in claim 5, wherein a second terminal of said first current source, a second terminal of said second current source, a second terminal of said third resistor, a second terminal of said sixth resistor, a source electrode of said ninth FET and a source electrode of said tenth FET are all connected to said power source terminal; and a drain electrode of said first FET, a drain electrode of said second FET, a second terminal of said third current source, a second terminal of said fourth current source and a second terminal of said fifth current source are all connected to said ground terminal.

7. A high speed signal detecting method, comprising a step of: providing a device comprising an input terminal, a reference terminal, an output terminal, a power source terminal, a ground terminal, a front-end receiver for comparing a signal of the input terminal with a signal of the reference terminal, a secondary amplifier for amplifying output signals VO1 and VO2 which are outputted by the front-end receiver, a final amplifier for amplifying output signals V2A and V2B which are outputted by the secondary amplifier and transforming the output signal V2A and the output signal V2B into a single-terminal output signal, and a biasing circuit for supplying the front-end receiver, the secondary amplifier and the final amplifier with bias current sources.

8. The high speed signal detecting method, as recited in claim 7, wherein the front-end receiver comprises a first FET which is connected to the input terminal and the ground terminal, and a second FET which is connected to the reference terminal and the ground terminal; the secondary amplifier comprises a third FET connected to the first FET, a fourth FET connected to the second FET, a fifth FET connected to the third FET, a sixth FET connected to the fourth FET, a first resistor connected to the third FET, a second resistor connected to the fourth FET, a third resistor which is connected to the first resistor, the second resistor and the power source terminal, a fourth resistor connected to the fifth FET, a fifth resistor connected to the sixth FET and a sixth resistor which is connected to the fourth resistor, the fifth resistor and the power source terminal; the final amplifier comprises a seventh FET connected to the fifth FET, an eighth FET which is connected to the sixth FET and the output terminal, a ninth FET which is connected to the seventh FET and the power source terminal, and a tenth FET which is connected to the seventh FET, the eighth FET, the ninth FET, the output terminal and the power source terminal; and the biasing circuit comprises a first current source which is connected to the first FET, the third FET and the power source terminal, a second current source which is connected to the second FET, the fourth FET and the power source terminal, a third current source which is connected to the third FET, the fourth FET and the power source terminal, a fourth current source which is connected to the fifth FET, the sixth FET and the power source terminal, and a fifth current source which is connected to the seventh FET, the eighth FET and the power source terminal.

9. The high speed signal detecting method, as recited in claim 8, further comprising steps of: inputting a high speed signal which is set to be at a fixed level by the reference terminal and inputting a high speed signal by the input terminal, comparing the high speed signal inputted by the input terminal with the high speed signal at the fixed level which is inputted by the reference terminal and then amplifying to obtain output signals VO1 and VO2 which enter the secondary amplifier; comparing the output signals VO1 with VO2 to obtain a first comparison result, amplifying the first comparison result to obtain output signals V2A and V2B and outputting the output signals V2A and V2B into the final amplifier by the secondary amplifier; and comparing the output signals V2A with V2B which enter the final amplifier to obtain a second comparison result, transforming the second comparison result into a single-terminal output signal and outputting the single-terminal output signal into the output terminal by the final amplifier.

10. The high speed signal detecting method, as recited in claim 9, wherein the fixed level pre-set by the reference terminal is a detection threshold value of the high speed signals.
